(19) United States
(12) Patent Application Publication
(10) Pub. No.: US 2025/0153542 A1
(43) Pub. Date: May 15, 2025

(54) VEHICLE THERMAL MANAGEMENT SYSTEM

(71) Applicants: HYUNDAI MOTOR COMPANY, Seoul (KR); KIA CORPORATION, Seoul (KR)

(72) Inventors: Gi Sang Yun, Incheon (KR); Jung Min Seo, Suwon-si (KR)

(73) Assignees: HYUNDAI MOTOR COMPANY, Seoul (KR); KIA CORPORATION, Seoul (KR)

(21) Appl. No.: 18/740,685

(22) Filed: Jun. 12, 2024

(30) Foreign Application Priority Data
Nov. 9, 2023 (KR) 10-2023-0154832

(51) Int. Cl. B60H 1/14; B60H 1/00; B60H 1/32; B60K 11/02; H01M 10/613; H01M 10/625; H01M 10/6568; H01M 10/663; H01M 10/667; H05K 7/20

(52) U.S. Cl. CPC B60H 1/143; B60H 1/00278; B60H 1/32284; H01M 10/613; H01M 10/625; H01M 10/6568; H01M 10/663; H01M 10/667; H05K 7/20309; H05K 7/20318; H05K 7/20327; H05K 7/20354; H05K 7/20936; B60H 2001/00307; B60K 11/02; H01M 2220/20

(57) ABSTRACT

A vehicle thermal management system includes: a cabin heating subsystem thermally connected to a cabin and including a cabin coolant circulation path configured to allow a cabin coolant to circulate; a power electronics (PE) cooling subsystem fluidly connected to a PE component and including a PE coolant circulation path configured to allow a PE coolant to circulate; and a battery cooling subsystem fluidly connected to a battery and including a battery coolant circulation path configured to allow a battery coolant to circulate. The vehicle thermal management system further includes a heat pump module thermally and fluidly connected to the cabin heating subsystem, the PE cooling subsystem, and the battery cooling subsystem. The heat pump module includes a refrigerant circulation path configured to allow a refrigerant to circulate.

### CROSS-REFERENCE TO RELATED APPLICATION

This application claims the benefit of and priority to Korean Patent Application No. 10-2023-0154832, filed on Nov. 9, 2023, in the Korean Intellectual Property Office, the disclosure of which is incorporated herein in its entirety by reference.

### TECHNICAL FIELD

The present disclosure relates to a vehicle thermal management system, and more particularly, to a vehicle thermal management system designed to efficiently transfer heat between a cabin heating subsystem, a power electronics cooling subsystem, and a battery cooling subsystem.

### BACKGROUND

With a growing emphasis on energy efficiency and environmental concerns, the development of eco-friendly vehicles capable of replacing internal combustion engine vehicles is becoming increasing important. Such eco-friendly vehicles are classified into electric vehicles, which are driven using fuel cells or electricity as a power source, and hybrid vehicles which are driven using an engine and a battery.

Electric vehicles may include a vehicle thermal management system for heating a passenger compartment (or cabin) and maintaining a battery and/or power electronic components at optimal temperatures. The vehicle thermal management system may include a cabin heating subsystem for heating the cabin, a power electronics (PE) cooling subsystem designed to maintain the PE components of a PE system at appropriate temperatures, and a battery cooling subsystem designed to maintain the battery at an appropriate temperature. The battery cooling subsystem may include a battery chiller and a battery radiator, and the PE cooling subsystem may include a PE radiator.

As for the layout of an electric bus according to the related art, the battery and the battery cooling subsystem may be disposed on a roof of a vehicle body, and the PE cooling subsystem and the cabin heating subsystem may be disposed on a floor of the vehicle body. Accordingly, the battery may be spaced apart from a cabin heating loop. Thus, waste heat of the battery may not be used in the cabin heating subsystem.

In addition, as the related art electric bus has a relatively large battery capacity, the heat generating amount of the battery in charging conditions may be significantly high, and the heat generating amount of the battery in driving conditions may be relatively low. Accordingly, the size of the battery radiator and the size of the battery chiller in the battery cooling subsystem to correspond to the charging conditions of the battery may relatively increase, resulting in increases in the number of components and weight of the vehicle thermal management system.

The vehicle thermal management system according to the related art may not efficiently transfer heat between the cabin heating subsystem, the battery cooling subsystem, and the PE cooling subsystem, thereby failing to efficiently use thermal energy while significantly wasting electrical energy.

The above information described in this background section is provided to assist in understanding the background of the present disclosure, and may include any technical concept which is not considered as the prior art that is already known to those having ordinary skill in the art.

### SUMMARY

The present disclosure has been made to solve the above-mentioned problems occurring in the prior art while advantages achieved by the prior art are maintained intact.

An aspect of the present disclosure provides a vehicle thermal management system designed to efficiently transfer heat between a cabin heating subsystem, a power electronics (PE) cooling subsystem, and a battery cooling subsystem through a heat pump module including a refrigerant cycle.

According to an aspect of the present disclosure, a vehicle thermal management system may include: a cabin heating subsystem thermally connected to a cabin. The cabin heating subsystem includes a cabin coolant circulation path configured to allow a cabin coolant to circulate. The vehicle thermal management system may further include: a power electronics (PE) cooling subsystem that is fluidly connected to a PE component and includes a PE coolant circulation path configured to allow a PE coolant to circulate; and a battery cooling subsystem that is fluidly connected to a battery and includes a battery coolant circulation path configured to allow a battery coolant to circulate. The vehicle thermal management system may further include: a heat pump module thermally and fluidly connected to the cabin heating subsystem, the PE cooling subsystem, and the battery cooling subsystem. The heat pump module includes a refrigerant circulation path configured to allow a refrigerant to circulate.

In one embodiment, the heat pump module may further include: a compressor, a condenser disposed on the downstream side of the compressor, an evaporator disposed on the downstream side of the condenser, and a heat exchanger configured to transfer heat between the refrigerant received from the compressor or the condenser and the PE coolant.

The cabin coolant circulation path may be thermally connected to the condenser, and the battery coolant circulation path may be thermally connected to the evaporator.

In another embodiment, the condenser may include a refrigerant passage fluidly connected to the refrigerant circulation path, and a coolant passage fluidly connected to the cabin coolant circulation path.

In one embodiment, the heat exchanger may include a refrigerant passage fluidly connected to the refrigerant circulation path, and a coolant passage fluidly connected to the PE coolant circulation path.

In one embodiment, the heat pump module may include a first expansion valve configured to expand the refrigerant flowing from the condenser to the heat exchanger.

In one embodiment, the evaporator may include: a refrigerant passage fluidly connected to the refrigerant circulation path, and a coolant passage fluidly connected to the battery coolant circulation path.

In one embodiment, the heat pump module may include a second expansion valve configured to expand the refrigerant flowing into the refrigerant passage of the evaporator.

In one embodiment, the heat pump module may further include a first control valve configured to allow the refrigerant discharged from the compressor to be directed to the condenser or to bypass the condenser.

In one embodiment, the heat pump module may further include a second control valve configured to allow the refrigerant discharged from the condenser to be directed to the heat exchanger or allow the refrigerant bypassing the condenser to be directed to the refrigerant passage of the heat exchanger.

In one embodiment, the cabin heating subsystem may include: a cabin radiator fluidly connected to the cabin coolant circulation path, a circulation pump forcing the cabin coolant to circulate, and a bypass line configured to allow the cabin coolant to bypass the heat pump module.

In one embodiment, the cabin heating subsystem may further include a control valve configured to allow the cabin coolant discharged from the cabin radiator to be directed to any one of the heat pump module and the bypass line.

In one embodiment, the PE cooling subsystem may include: a circulation pump forcing the PE coolant to circulate, a PE radiator configured to cool the PE coolant through heat exchange with ambient air, and a bypass line configured to allow the PE coolant to bypass the PE radiator.

In one embodiment, the PE cooling subsystem may further include a control valve configured to allow the PE coolant discharged from the coolant passage of the PE component to be directed to any one of the PE radiator and the bypass line.

### BRIEF DESCRIPTION OF THE DRAWINGS

The above and other objects, features and advantages of the present disclosure should be more apparent from the following detailed description taken in conjunction with the accompanying drawings:

FIG. 1 illustrates a vehicle thermal management system according to an embodiment of the present disclosure;

FIG. 2 illustrates a heat pump module of a vehicle thermal management system according to an embodiment of the present disclosure;

FIG. 3 illustrates a state in which a cabin heating subsystem, a power electronics (PE) cooling subsystem, and a battery cooling subsystem are fluidly connected to a heat pump module in a vehicle thermal management system according to an embodiment of the present disclosure;

FIG. 4 illustrates a flow direction of a refrigerant through the heat pump module in the state illustrated in FIG. 3;

FIG. 5 illustrates a state in which a PE cooling subsystem and a battery cooling subsystem are fluidly connected to a heat pump module in a vehicle thermal management system according to an embodiment of the present disclosure; and

FIG. 6 illustrates a flow direction of a refrigerant through the heat pump module in the state illustrated in FIG. 5.

The drawings described herein are for illustration purposes only and are not intended to limit the scope of the present disclosure in any way.

### DETAILED DESCRIPTION

Hereinafter, some embodiments of the present disclosure are described in detail with reference to the accompanying drawings. In the drawings, the same reference numerals are used throughout to designate the same or equivalent elements. In addition, a detailed description of well-known techniques associated with the present disclosure is ruled out in order not to unnecessarily obscure the gist of the present disclosure.

Terms such as first, second, A, B, (a), and (b) may be used to describe the elements in exemplary embodiments of the present disclosure. These terms are only used to distinguish one element from another element, and the intrinsic features, sequence or order, and the like of the corresponding elements are not limited by the terms. Unless otherwise defined, all terms used herein, including technical or scientific terms, have the same meanings as those generally understood by those with ordinary knowledge in the field of art to which the present disclosure belongs. Such terms as those defined in a generally used dictionary are to be interpreted as having meanings equal to the contextual meanings in the relevant field of art, and are not to be interpreted as having ideal or excessively formal meanings unless clearly defined as having such in the present application. When a component, device, element, or the like of the present disclosure is described as having a purpose or performing an operation, function, or the like, the component, device, or element should be considered herein as being “configured to” meet that purpose or to perform that operation or function.

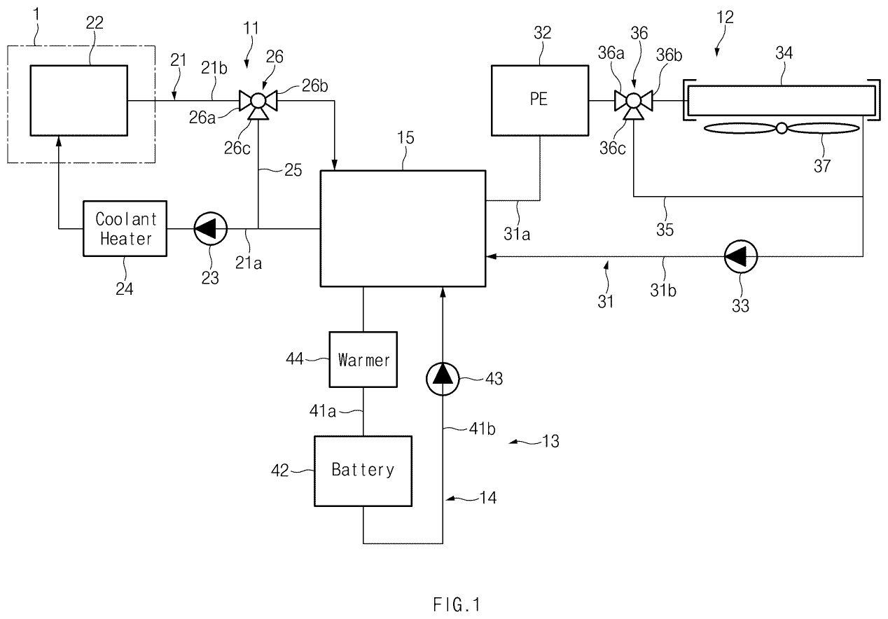

Referring to FIG. 1, a vehicle thermal management system according to an embodiment of the present disclosure may include: a cabin heating subsystem 11 thermally connected to a cabin (or passenger compartment) 1; a power electronics (PE) cooling subsystem 12 thermally connected to a PE component 32; a battery cooling subsystem 13 thermally connected to a battery 42; and a heat pump module 15 thermally and fluidly connected to the cabin heating subsystem 11, the PE cooling subsystem 12, and the battery cooling subsystem 13.

The cabin heating subsystem 11 may include: a cabin coolant circulation path 21 configured to allow a cabin coolant to circulate, a cabin radiator 22 fluidly connected to the cabin coolant circulation path 21, a circulation pump 23 forcing the cabin coolant to circulate, and a heater 24 heating the cabin coolant.

The cabin coolant circulation path 21 may be fluidly connected to the cabin radiator 22, the heater 24, and the heat pump module 15. According to an embodiment, the cabin coolant circulation path 21 may include an inlet line 21a connected to an inlet of the cabin radiator 22, and an outlet line 21b connected to an outlet of the cabin radiator 22.

The circulation pump 23 may be provided in various positions of the cabin coolant circulation path 21. For example, the circulation pump 23 may be disposed in the inlet line 21a.

The heater 24 may be disposed in the inlet line 21a of the cabin coolant circulation path 21, and the heater 24 may be configured to heat the cabin coolant directed to the cabin radiator 22.

The cabin heating subsystem 11 may include a bypass line configured to allow the cabin coolant to bypass the heat pump module 15. The bypass line 25 may be configured to connect a downstream point of the cabin radiator 22 and an upstream point of the cabin radiator 22. An inlet of the bypass line 25 may be connected to the outlet line 21b, and an outlet of the bypass line 25 may be connected to the inlet line 21a.

The cabin heating subsystem 11 may include a control valve 26 disposed at a point to which the inlet of the bypass line 25 and the outlet line 21b of the cabin coolant circulation path 21 are connected. The control valve 26 may be configured to control the flow of the cabin coolant in a manner that allows the cabin coolant discharged from the cabin radiator 22 to be directed to any one of the heat pump module 15 and the bypass line 25.

The control valve 26 may include an inlet port 26a communicating with the outlet of the cabin radiator 22, a first outlet port 26b communicating with the heat pump module 15, and a second outlet port 26c communicating with the inlet of the bypass line 25.

In a state in which the control valve 26 performs a first switching operation that allows the inlet port 26a to communicate with the first outlet port 26b, the cabin coolant discharged from the cabin radiator 22 may be directed to the heat pump module 15.

In a state in which the control valve 26 performs a second switching operation that allows the inlet port 26a to communicate with the second outlet port 26c, the cabin coolant discharged from the cabin radiator 22 may be directed to the bypass line 25 so that the cabin coolant may bypass the heat pump module 15.

As the circulation pump 23 operates, the cabin coolant may circulate through the cabin coolant circulation path 21. The cabin coolant may be directed to the cabin radiator 22 through the inlet line 21a of the cabin coolant circulation path 21. When the heater 24 operates, the cabin coolant may be heated to a predetermined temperature, and the heated cabin coolant may release heat to the cabin through the cabin radiator 22 so that the cabin may be heated. The cabin coolant discharged from the cabin radiator 22 may be directed to the heat pump module 15 or the bypass line 25 according to the switching operations of the control valve 26.

The PE cooling subsystem 12 may include a PE coolant circulation path 31 configured to allow a PE coolant to circulate, the PE component 32 fluidly connected to the PE coolant circulation path 31, a circulation pump 33 forcing the PE coolant to circulate, and a PE radiator 34 configured to cool the PE coolant through heat exchange with ambient air.

The PE component 32 may have a coolant passage provided inside or outside thereof, and the PE coolant may pass through the coolant passage of the PE component 32. The PE component 32 may include an integrated charging control unit (ICCU), a front-wheel-side inverter, a rear-wheel-side inverter, a rear-wheel-side motor, an oil cooler connected to the rear-wheel-side motor, a front-wheel-side motor, an oil cooler connected to the front-wheel-side motor, and the like.

The PE coolant circulation path 31 may be fluidly connected to the PE component 32, the PE radiator 34, and the heat pump module 15. According to an embodiment, the PE coolant circulation path 31 may include an inlet line 31a connected to an inlet of the coolant passage of the PE component 32, and an outlet line 31b connected to an outlet of the coolant passage of the PE component 32.

The circulation pump 33 may be provided in various positions of the PE coolant circulation path 31. For example, the circulation pump 33 may be disposed in the outlet line 31b.

The PE radiator 34 may be disposed on the downstream side of the PE component 32, and the PE radiator 34 may be configured to contact the ambient air through a grille of the vehicle and the like. A cooling fan 37 may be disposed adjacent to the PE radiator 34. The PE radiator 34 may be configured to cool the PE coolant by allowing the PE coolant discharged from the coolant passage of the PE component 32 to exchange heat with the ambient air.

The PE cooling subsystem 12 may include a bypass line 35 configured to allow the PE coolant to bypass the PE radiator 34. The bypass line 35 may be configured to connect an upstream point of the PE radiator 34 and a downstream point of the PE radiator 34. An inlet of the bypass line 35 may be connected to the outlet line 31b at the upstream point of the PE radiator 34, and an outlet of the bypass line 35 may be connected to the outlet line 31b at the downstream point of the PE radiator 34.

The PE cooling subsystem 12 may include a control valve 36 at a point to which the bypass line 35 and the outlet line 31b of the PE coolant circulation path 31 are connected. The control valve 36 may control the flow of the PE coolant in a manner that allows the PE coolant discharged from the coolant passage of the PE component 32 to be directed to any one of the PE radiator 34 and the bypass line 35.

The control valve 36 may include an inlet port 36a communicating with the outlet of the coolant passage of the PE component 32, a first outlet port 36b communicating with an inlet of the PE radiator 34, and a second outlet port 36c communicating with the inlet of the bypass line 35.

In a state in which the control valve 36 performs a first switching operation that allows the inlet port 36a to communicate with the first outlet port 36b, the PE coolant discharged from the coolant passage of the PE component 32 may be directed to the PE radiator 34.

In a state in which the control valve 36 performs a second switching operation that allows the inlet port 36a to communicate with the second outlet port 36c, the PE coolant discharged from the coolant passage of the PE component 32 may be directed to the bypass line 35 so that the PE coolant may bypass the PE radiator 34.

As the circulation pump 33 operates, the PE coolant may circulate through the PE coolant circulation path 31. The PE coolant may be directed to the coolant passage of the PE component 32 through the inlet line 31a of the PE coolant circulation path 31. The PE coolant discharged from the coolant passage of the PE component 32 may be directed to the PE radiator 34 or the bypass line 35 according to the switching operations of the control valve 36.

The battery cooling subsystem 13 may include: a battery coolant circulation path 41 configured to allow a battery coolant to circulate, the battery 42 fluidly connected to the battery coolant circulation path 41, a circulation pump 43 forcing the battery coolant to circulate, and a battery warmer 44 warming up the battery coolant.

The battery 42 may have a coolant passage provided inside or outside thereof, and the battery coolant may pass through the coolant passage of the battery 42.

The battery coolant circulation path 41 may be fluidly connected to the battery 42, the battery warmer 44, and the heat pump module 15. According to an embodiment, the battery coolant circulation path 41 may include: an inlet line 41a connected to an inlet of the coolant passage of the battery 42, and an outlet line 41b connected to an outlet of the coolant passage of the battery 42.

The circulation pump 43 may be provided in various positions of the battery coolant circulation path 41. For example, the circulation pump 43 may be disposed in the outlet line 41b.

The battery warmer 44 may be disposed on the upstream side of the battery 42, and the battery warmer 44 may be configured to warm up the battery coolant.

As the circulation pump 43 operates, the battery coolant may circulate through the battery coolant circulation path 41. The battery coolant may be directed to the coolant passage of the battery 42 through the inlet line 41a of the battery coolant circulation path 41. The battery coolant discharged from the coolant passage of the battery 42 may return to the coolant passage of the battery 42 through the heat pump module 15.

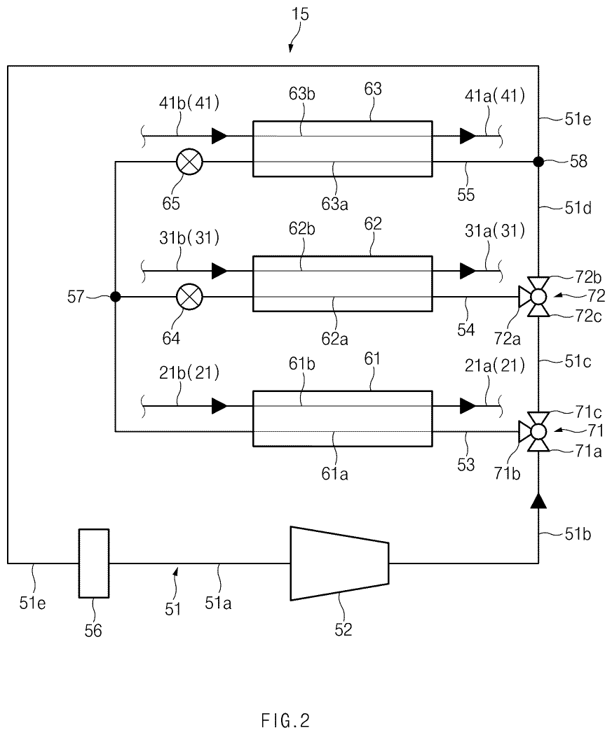

Referring to FIG. 2, the heat pump module 15 may include: a refrigerant circulation path 51 configured to allow a phase-changing refrigerant to circulate, a compressor 52 fluidly connected to the refrigerant circulation path 51, and an accumulator 56 disposed on the upstream side of the compressor 52. The heat pump module 15 may further include: a condenser 61 thermally connected to the cabin coolant circulation path 21 of the cabin heating subsystem 11, a heat exchanger 62 thermally connected to the PE coolant circulation path 31 of the PE cooling subsystem 12, and an evaporator 63 thermally connected to the battery coolant circulation path 41 of the battery cooling subsystem 13.

The compressor 52 may be configured to compress the refrigerant to thereby allow the refrigerant to circulate. According to an embodiment, the compressor 52 may be an electric compressor driven by electric energy.

The accumulator 56 may be disposed on the upstream side of the compressor 52, and the accumulator 56 may separate a liquid refrigerant from the refrigerant, thereby preventing the liquid refrigerant from flowing into the compressor 52.

The condenser 61 may be disposed on the downstream side of the compressor 52, and be thermally connected to the cabin coolant circulation path 21 so that it may be configured to transfer heat between the cabin coolant and the refrigerant. In one form, the condenser 61 may include a refrigerant passage 61a through which the refrigerant passes, and a coolant passage 61b through which the cabin coolant passes. The refrigerant passage 61a may be configured to selectively allow the high-pressure refrigerant discharged from the compressor 52 to pass therethrough. The coolant passage 61b may be fluidly connected to the outlet line 21b and the inlet line 21a of the cabin coolant circulation path 21. The cabin coolant may sequentially pass through the outlet line 21b of the cabin coolant circulation path 21, the coolant passage 61b, and the inlet line 21a of the cabin coolant circulation path 21. The refrigerant discharged from the compressor 52 may be in a relatively high-temperature, high-pressure state. The temperature of the cabin coolant discharged from the outlet line 21b of the cabin coolant circulation path 21 may be lower than the temperature of the refrigerant discharged from the compressor 52. When the high-temperature refrigerant discharged from the compressor 52 passes through the refrigerant passage 61a of the condenser 61, and the cabin coolant discharged from the outlet line 21b of the cabin coolant circulation path 21 passes through the coolant passage 61b of the condenser 61, heat may be transferred from the relatively high-temperature refrigerant to the relatively low-temperature cabin coolant. Accordingly, the refrigerant may be condensed, and the cabin coolant may be heated.

The heat exchanger 62 may be configured to transfer heat between the refrigerant received from the condenser 61 or the compressor 52 and the PE coolant. The heat exchanger 62 may be thermally connected to the PE coolant circulation path 31 of the PE cooling subsystem 12 so that it may be configured to transfer heat between the PE coolant and the refrigerant. In one embodiment, the heat exchanger 62 may include: a refrigerant passage 62a through which the refrigerant passes, and a coolant passage 62b through which the PE coolant passes. The refrigerant passage 62a of the heat exchanger 62 may be configured to receive the refrigerant discharged from the refrigerant passage 61a of the condenser 61 or the compressor 52. The coolant passage 62b of the heat exchanger 62 may be fluidly connected to the outlet line 31b and the inlet line 31a of the PE coolant circulation path 31. The PE coolant may sequentially pass through the outlet line 31b of the PE coolant circulation path 31, the coolant passage 62b, and the inlet line 31a of the PE coolant circulation path 31.

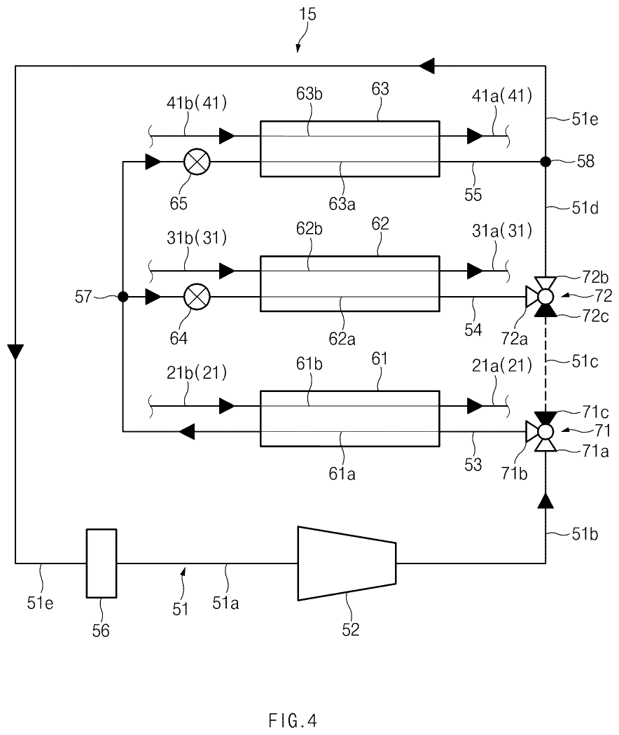

According to an embodiment, as illustrated in FIG. 4, as the high-temperature, high-pressure refrigerant discharged from the compressor 52 passes through the refrigerant passage 61a of the condenser 61, the refrigerant may be condensed by the condenser 61. Since the refrigerant is condensed by the condenser 61, the temperature of the refrigerant discharged from the refrigerant passage 61a of the condenser 61 may be relatively low, and the temperature of the PE coolant discharged from the outlet line 31b of the PE coolant circulation path 31 may be higher than the refrigerant discharged from the refrigerant passage 61a of the condenser 61. When the refrigerant discharged from the refrigerant passage 61a of the condenser 61 passes through the refrigerant passage 62a of the heat exchanger 62, and the PE coolant discharged from the outlet line 31b of the PE coolant circulation path 31 passes through the coolant passage 62b of the heat exchanger 62, heat may be transferred from the relatively high-temperature PE coolant to the relatively low-temperature refrigerant. Accordingly, the refrigerant may be evaporated, and the PE coolant may be cooled.

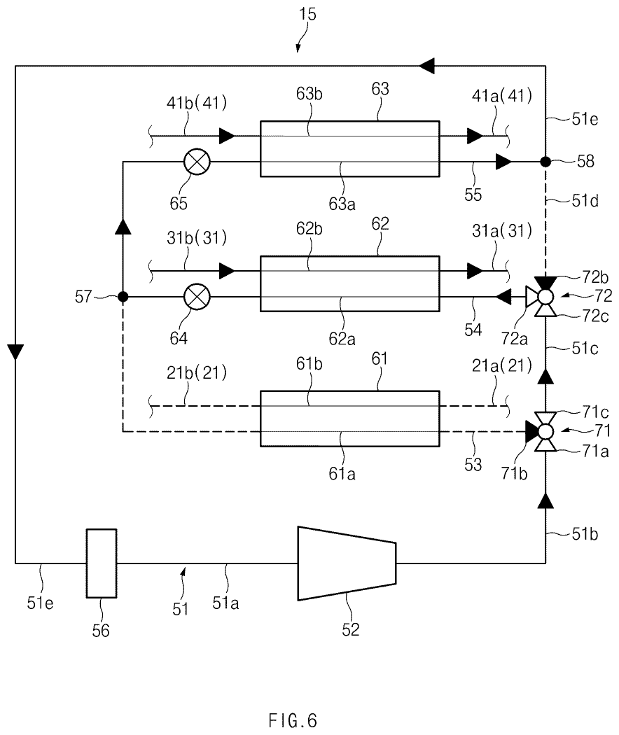

According to another embodiment, as illustrated in FIG. 6, the refrigerant discharged from the compressor 52 may be in a high-temperature, high-pressure state, and the temperature of the PE coolant discharged from the outlet line 31b of the PE coolant circulation path 31 may be lower than the temperature of the refrigerant discharged from the compressor 52. When the refrigerant discharged from the compressor 52 passes through the refrigerant passage 62a of the heat exchanger 62, and the PE coolant discharged from the outlet line 31b of the PE coolant circulation path 31 passes through the coolant passage 62b of the heat exchanger 62, heat may be transferred from the relatively high-temperature refrigerant to the relatively low-temperature PE coolant. Accordingly, the refrigerant may be condensed, and the PE coolant may be heated.

As described above, the refrigerant passage 62a of the heat exchanger 62 may receive the refrigerant discharged from the refrigerant passage 61a of the condenser 61 or the compressor 52, and transfer heat between the refrigerant passing through the refrigerant passage 62a of the heat exchanger 62 and the PE coolant passing through the coolant passage 62b of the heat exchanger 62 so that the heat exchanger 62 may evaporate or condense the refrigerant, and heat or cool the PE coolant.

The evaporator 63 may be disposed on the downstream side of the condenser 61 in a refrigerant flow direction. The evaporator 63 may be thermally connected to the battery coolant circulation path 41 of the battery cooling subsystem 13 so that it may be configured to transfer heat between the battery coolant and the refrigerant. In one embodiment, the evaporator 63 may include: a refrigerant passage 63a through which the refrigerant passes, and a coolant passage 63b through which the battery coolant passes. The refrigerant passage 63a may be configured to allow the refrigerant discharged from the refrigerant passage 61a of the condenser 61 or the refrigerant discharged from the refrigerant passage 62a of the heat exchanger 62 to pass therethrough. The coolant passage 63b may be fluidly connected to the outlet line 41b and the inlet line 41a of the battery coolant circulation path 41. The battery coolant may sequentially pass through the outlet line 41b of the battery coolant circulation path 41, the coolant passage 63b, and the inlet line 41a of the battery coolant circulation path 41. The temperature of the refrigerant discharged from the refrigerant passage 61a of the condenser 61 or the refrigerant passage 62a of the heat exchanger 62 may be relatively low, and the temperature of the battery coolant discharged from the outlet line 41b of the battery coolant circulation path 41 may be higher than the temperature of the refrigerant discharged from the refrigerant passage 61a of the condenser 61 or the refrigerant passage 62a of the heat exchanger 62. When the refrigerant discharged from the refrigerant passage 61a of the condenser 61 or the refrigerant discharged from the refrigerant passage 62a of the heat exchanger 62 passes through the refrigerant passage 63a, and the battery coolant discharged from the outlet line 41b of the battery coolant circulation path 41 passes through the coolant passage 63b, heat may be transferred from the relatively high-temperature battery coolant to the relatively low-temperature refrigerant. Accordingly, the refrigerant may be evaporated, and the battery coolant may be cooled.

The refrigerant circulation path 51 may include: an inlet line 51a connected to an inlet of the compressor 52, an outlet line 51b connected to an outlet of the compressor 52, a first downstream line 51c connected to the outlet line 51b, and a second downstream line 51d connected to the first downstream line 51c, an upstream line 51e connected to the second downstream line 51d. The refrigerant circulation path 51 may further include: a first branch line 53 branching off from the outlet line 51b, a second branch line 54 branching off from the first downstream line 51c, and a third branch line 55 branching off from the second downstream line 51d.

The inlet line 51a may be a refrigerant conduit extending from an outlet of the accumulator 56 to the inlet of the compressor 52. The refrigerant discharged from the accumulator 56 may be directed to the inlet of the compressor 52 through the inlet line 51a.

The outlet line 51b may be a refrigerant conduit extending from the outlet of the compressor 52, and the first branch line 53 and the first downstream line 51c may be connected to the outlet line 51b.

The first downstream line 51c may be a refrigerant conduit connected to an outlet of the outlet line 51b, and the second branch line 54 and the second downstream line 51d may be connected to the first downstream line 51c.

The second downstream line 51d may be a refrigerant conduit connected to an outlet of the first downstream line 51c, and the second branch line 54 and the first downstream line 51c may be connected to the second downstream line 51d.

The upstream line 51e may be a refrigerant conduit connecting the second downstream line 51d and the accumulator 56. The third branch line 55 and the second downstream line 51d may be connected to the upstream line 51e at a connection point 58.

The first branch line 53 may be connected to a downstream point of the compressor 52 in the refrigerant circulation path 51, and the condenser 61 may be fluidly connected to the first branch line 53. In other words, the condenser 61 may be fluidly connected to the refrigerant circulation path 51 through the first branch line 53. In one embodiment, the first branch line 53 may branch off from a connection point between the outlet line 51b and the first downstream line 51c, and the condenser 61 may be disposed in the first branch line 53. The refrigerant discharged from the compressor 52 may be directed to the refrigerant passage 61a of the condenser 61 through the first branch line 53. Thus, the condenser 61 may be disposed in the first branch line 53 branching off from the downstream side of the compressor 52, and the refrigerant passage 61a of the condenser 61 may receive the refrigerant discharged from the compressor 52 through the first branch line 53.

The second branch line 54 may branch off from a downstream point of a branch point of the first branch line 53 in the refrigerant circulation path 51. In one form, the second branch line 54 may branch off from a connection point between the first downstream line 51c and the second downstream line 51d, and the heat exchanger 62 may be disposed in the second branch line 54. The second branch line 54 may be connected to the first branch line 53 at a connection point 57. The refrigerant discharged from the refrigerant passage 61a of the condenser 61 may be directed to the refrigerant passage 62a of the heat exchanger 62 through the first branch line 53 (see FIG. 4) or the refrigerant discharged from the compressor 52 may be directed to the refrigerant passage 62a of the heat exchanger 62 through the first downstream line 51c and the second branch line 54 (see FIG. 6). Thus, the heat exchanger 62 may be disposed in the second branch line 54 branching off from the downstream side of the compressor 52, and the second branch line 54 may be connected to the first branch line 53 through the connection point 57. The refrigerant passage 62a of the heat exchanger 62 may receive the refrigerant discharged from the refrigerant passage 61a of the condenser 61 through the first branch line 53 and the second branch line 54 or receive the refrigerant discharged from the compressor 52 through the first downstream line 51c and the second branch line 54.

The third branch line 55 may branch off from a downstream point of a branch point of the second branch line 54 in the refrigerant circulation path 51. In one embodiment, the third branch line 55 may branch off from the connection point 58 between the second downstream line 51d and the upstream line 51e, and the evaporator 63 may be disposed in the third branch line 55. The third branch line 55 may be connected to the first branch line 53 and the second branch line 54 at the connection point 57. A portion of the refrigerant discharged from the refrigerant passage 61a of the condenser 61 may be directed to the refrigerant passage 63a of the evaporator 63 through the first branch line 53 and the third branch line 55 (see FIG. 4) or the refrigerant discharged from the refrigerant passage 62a of the heat exchanger 62 may be directed to the refrigerant passage 63a of the evaporator 63 through the second branch line 54 and the third branch line 55 (see FIG. 6). Thus, the evaporator 63 may be disposed in the third branch line 55 branching off from the downstream side of the compressor 52, the third branch line 55 may be connected to the first branch line 53 and the second branch line 54 through the connection point 57, and the refrigerant passage 63a of the evaporator 63 may receive the refrigerant discharged from the refrigerant passage 61a of the condenser 61 through the first branch line 53 and the third branch line 55 or receive the refrigerant discharged from the refrigerant passage 62a of the heat exchanger 62 through the second branch line 54 and the third branch line 55.

The heat pump module 15 may include a first expansion valve 64 disposed between the refrigerant passage 61a of the condenser 61 and the refrigerant passage 62a of the heat exchanger 62. The first expansion valve 64 may be configured to expand the refrigerant flowing from the refrigerant passage 61a of the condenser 61 to the refrigerant passage 62a of the heat exchanger 62. The opening degree of the first expansion valve 64 may be varied by a controller (not shown). As the opening degree of the first expansion valve 64 is varied, the flow rate of the refrigerant into the refrigerant passage 62a of the heat exchanger 62 may be varied. According to an embodiment, the first expansion valve 64 may be an electronic expansion valve (EXV) having an actuator. The actuator may have a shaft which is movable to open or close an orifice formed in a valve body of the first expansion valve 64, and the position of the shaft may be varied depending on the rotation direction, rotation degree, and the like of the actuator, and the opening degree of the orifice of the first expansion valve 64 may be varied accordingly. The controller may control the operation of the actuator. The first expansion valve 64 may be a full open type electronic expansion valve (EXV). When the refrigerant is not evaporated by the heat exchanger 62, the first expansion valve 64 may be fully opened (the opening degree of the first expansion valve 64 may be 100%) so that the refrigerant may pass through the first expansion valve 64 without resistance. Thus, the refrigerant may not be expanded by the first expansion valve 64.

The heat pump module 15 may include a second expansion valve 65 configured to expand the refrigerant flowing into the refrigerant passage 63a of the evaporator 63. The opening degree of the second expansion valve 65 may be varied by the controller (not shown). As the opening degree of the second expansion valve 65 is varied, the flow rate of the refrigerant into the refrigerant passage 63a of the evaporator 63 may be varied. According to an embodiment, the second expansion valve 65 may be an EXV having an actuator. The actuator may have a shaft which is movable to open or close an orifice formed in a valve body of the second expansion valve 65, and the position of the shaft may be varied depending on the rotation direction, rotation degree, and the like of the actuator, and the opening degree of the orifice of the second expansion valve 65 may be varied accordingly. The controller may control the operation of the actuator. The second expansion valve 65 may be a full open type electronic expansion valve (EXV). When the refrigerant is not evaporated by the evaporator 63, the second expansion valve 65 may be fully opened (the opening degree of the second expansion valve 65 may be 100%) so that the refrigerant may pass through the second expansion valve 65 without resistance. Thus, the refrigerant may not be expanded by the second expansion valve 65.

The heat pump module 15 may include a first control valve 71 disposed between the outlet line 51b, the first downstream line 51c, and the first branch line 53. The first control valve 71 may control the flow of the refrigerant in a manner that allows the refrigerant discharged from the compressor 52 to be directed to the refrigerant passage 61a of the condenser 61 or to bypass the refrigerant passage 61a of the condenser 61.

The first control valve 71 may include an inlet port 71a communicating with the outlet of the compressor 52 through the outlet line 51b, a first outlet port 71b communicating with the refrigerant passage 61a of the condenser 61 through the first branch line 53, and a second outlet port 71c communicating with the first downstream line 51c.

In a state in which the first control valve 71 performs a first switching operation that allows the inlet port 71a to communicate with the first outlet port 71b, the refrigerant discharged from the compressor 52 may be directed to the refrigerant passage 61a of the condenser 61 (see FIG. 4).

In a state in which the first control valve 71 performs a second switching operation that allows the inlet port 71a to communicate with the second outlet port 71c, the refrigerant discharged from the compressor 52 may be directed to the first downstream line 51c so that it may bypass the refrigerant passage 61a of the condenser 61. After the refrigerant discharged from the compressor 52 bypasses the refrigerant passage 61a of the condenser 61, it may be directed to the refrigerant passage 62a of the heat exchanger 62 through the first downstream line 51c and the second branch line 54 (see FIG. 6).

The heat pump module 15 may include a second control valve 72 disposed between the first downstream line 51c, the second downstream line 51d, and the second branch line 54. The second control valve 72 may be configured to control the flow of the refrigerant in a manner that allows the refrigerant discharged from the refrigerant passage 61a of the condenser 61 to be directed to the refrigerant passage 62a of the heat exchanger 62 or allows the refrigerant bypassing the refrigerant passage 61a of the condenser 61 to be directed to the refrigerant passage 62a of the heat exchanger 62.

The second control valve 72 may include an inlet port 72a communicating with the refrigerant passage 62a of the heat exchanger 62 through the second branch line 54, a first outlet port 72b communicating with the second downstream line 51d, and a second outlet port 72c communicating with the first downstream line 51c.

In a state in which the second control valve 72 performs a first switching operation that allows the inlet port 72a to communicate with the first outlet port 72b, the refrigerant discharged from the refrigerant passage 61a of the condenser 61 may be directed to the refrigerant passage 62a of the heat exchanger 62, and the refrigerant discharged from the refrigerant passage 62a of the heat exchanger 62 may be directed to the second downstream line 51d (see FIG. 4).

In a state in which the second control valve 72 performs a second switching operation that allows the inlet port 72a to communicate with the second outlet port 72c, the refrigerant bypassing the refrigerant passage 61a of the condenser 61 through the first downstream line 51c may be directed to the refrigerant passage 62a of the heat exchanger 62, and the refrigerant discharged from the refrigerant passage 62a of the heat exchanger 62 may be directed to the refrigerant passage 63a of the evaporator 63 (see FIG. 6).

Referring to FIG. 4, in a state in which the first control valve 71 performs the first switching operation that allows the inlet port 71a to communicate with the first outlet port 71b, and the second control valve 72 performs the first switching operation that allows the inlet port 72a to communicate with the first outlet port 72b, the refrigerant discharged from the compressor 52 may pass through the refrigerant passage 61a of the condenser 61, and then be distributed from the connection point 57 to the refrigerant passage 62a of the heat exchanger 62 and the refrigerant passage 63a of the evaporator 63. The refrigerant discharged from the refrigerant passage 62a of the heat exchanger 62 and the refrigerant discharged from the refrigerant passage 63a of the evaporator 63 may be joined at the connection point 58 and be directed to the upstream line 51e.

Referring to FIG. 6, in a state in which the first control valve 71 performs the second switching operation that allows the inlet port 71a to communicate with the second outlet port 71c, and the second control valve 72 performs the second switching operation that allows the inlet port 72a to communicate with the second outlet port 72c, the refrigerant discharged from the compressor 52 may bypass the refrigerant passage 61a of the condenser 61, and be directed to the refrigerant passage 62a of the heat exchanger 62 through the first downstream line 51c and the second branch line 54. The refrigerant discharged from the refrigerant passage 62a of the heat exchanger 62 may be directed to the refrigerant passage 63a of the evaporator 63 through the first expansion valve 64, and the refrigerant discharged from the refrigerant passage 63a of the evaporator 63 may be directed to the upstream line 51e.

In a condition of low outdoor temperatures such as in winter, the controller may determine whether waste heat of the battery 42 and waste heat of the PE component 32 are available for heating the cabin 1 by comparing the interior temperature of the cabin 1, the temperature of the cabin coolant circulating in the cabin coolant circulation path 21 of the cabin heating subsystem 11, and the temperature of the refrigerant circulating in the refrigerant circulation path 51 of the heat pump module 15. When it is determined that the waste heat of the battery 42 and the waste heat of the PE component 32 are available for heating the cabin 1, the controller may allow the cabin coolant to circulate through the heat pump module 15.

When it is determined that the waste heat of the battery 42 and the waste heat of the PE component 32 are not available for heating the cabin 1, the controller may allow the control valve 26 of the cabin heating subsystem 11 to perform the second switching operation. Accordingly, the inlet port 26a may be allowed to communicate with the second outlet port 26c so that the cabin coolant discharged from the cabin radiator 22 may be directed to the bypass line 25 to thereby bypass the heat pump module 15. As the heater 24 operates, the cabin coolant may be heated by the heater 24, and the heated cabin coolant may heat the cabin 1 through the cabin radiator 22. In other words, in a condition in which the waste heat of the battery 42 and the waste heat of the PE component 32 are not available for heating the cabin 1, the cabin coolant may not circulate through the heat pump module 15.

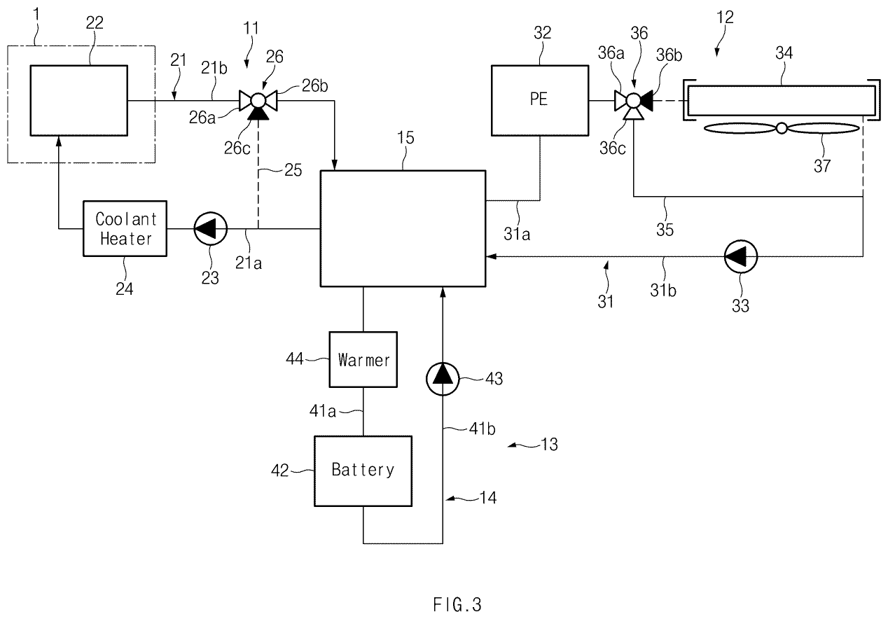

FIG. 3 illustrates a state in which the waste heat of the battery 42 and the waste heat of the PE component 32 are transferred to the cabin heating subsystem 11 through the heat pump module 15 as the cabin heating subsystem 11, the PE cooling subsystem 12, and the battery cooling subsystem 13 are thermally connected to the heat pump module 15 in winter.

Referring to FIG. 3, when it is determined that the waste heat of the battery 42 and the waste heat of the PE component 32 are available for heating the cabin 1, the controller may allow the control valve 26 of the cabin heating subsystem 11 to perform the first switching operation. Accordingly, the inlet port 26a may be allowed to communicate with the first outlet port 26b so that the cabin coolant discharged from the cabin radiator 22 may not be directed to the bypass line 25, but be directed to the heat pump module 15. In other words, in a condition in which the waste heat of the battery 42 and the waste heat of the PE component 32 are available for heating the cabin 1, the cabin coolant may circulate through the heat pump module 15.

Referring to FIG. 3, the controller may allow the control valve 36 of the PE cooling subsystem 12 to perform the second switching operation. Accordingly, the inlet port 36a may be allowed to communicate with the second outlet port 36c so that the PE coolant discharged from the coolant passage of the PE component 32 may be directed to the heat pump module 15 through the bypass line 35. In addition, the battery coolant discharged from the battery 42 may be directed to the heat pump module 15.

Referring to FIG. 4, the controller may allow the first control valve 71 to perform the first switching operation so that the inlet port 71a may communicate with the first outlet port 71b. Accordingly, the refrigerant discharged from the compressor 52 may pass through the refrigerant passage 61a of the condenser 61, and the cabin coolant discharged from the outlet line 21b of the cabin coolant circulation path 21 may pass through the coolant passage 61b. As a result, heat may be transferred from the relatively high-temperature refrigerant to the relatively low-temperature cabin coolant so that the refrigerant may be condensed, and the cabin coolant may be heated.

Referring to FIG. 4, the controller may allow the second control valve 72 to perform the first switching operation so that the inlet port 72a may communicate with the first outlet port 72b, and the controller may control the actuator of the first expansion valve 64 in a manner that opens the first expansion valve 64 to a predetermined opening degree depending on the temperature of the PE coolant. Accordingly, a portion of the refrigerant discharged from the refrigerant passage 61a of the condenser 61 may be expanded by the first expansion valve 64 and pass through the refrigerant passage 62a of the heat exchanger 62 through the second branch line 54, and the PE coolant discharged from the outlet line 31b of the PE coolant circulation path 31 may pass through the coolant passage 62b of the heat exchanger 62. As a result, heat may be transferred from the relatively high-temperature PE coolant to the relatively low-temperature refrigerant so that the refrigerant may be evaporated, and the PE coolant may be cooled.

Referring to FIG. 4, the controller may control the actuator of the second expansion valve 65 in a manner that opens the second expansion valve 65 to a predetermined opening degree depending on the temperature of the battery 42. A remaining portion of the refrigerant discharged from the refrigerant passage 61a of the condenser 61 may be expanded by the second expansion valve 65 and pass through the refrigerant passage 63a of the evaporator 63 through the third branch line 55, and the battery coolant discharged from the outlet line 41b of the battery coolant circulation path 41 may pass through the coolant passage 63b of the evaporator 63. As a result, heat may be transferred from the relatively high-temperature battery coolant to the relatively low-temperature refrigerant so that the refrigerant may be evaporated, and the battery coolant may be cooled.

Referring to FIG. 4, the refrigerant evaporated by the heat exchanger 62 and the refrigerant evaporated by the evaporator 63 may be joined at the connection point 58 and then be directed to the compressor 52 through the accumulator 56.

As described above, in a state in which the cabin heating subsystem 11, the PE cooling subsystem 12, and the battery cooling subsystem 13 are thermally connected to the heat pump module 15 in winter, the refrigerant in the evaporator 63 may absorb heat from the battery coolant, the refrigerant in the heat exchanger 62 may absorb heat from the PE coolant, and the cabin coolant in the condenser 61 may absorb heat from the refrigerant so that the cabin coolant may absorb the waste heat of the PE component 32 and the waste heat of the battery 42. Accordingly, refrigerant evaporation performance may be significantly improved, refrigerant compression efficiency of the compressor 52 may be improved, and refrigerant condensation performance and cabin coolant heating performance of the condenser 61 may be significantly improved.

According to the embodiments of the present disclosure, the waste heat of the battery 42 and the waste heat of the PE component 32 may be available for heating the cabin 1 in winter. Accordingly, a battery radiator may be removed, and thus the manufacturing cost may be relatively reduced. The operating time of the cooling fan 37 of the PE cooling subsystem 12 may be reduced, and thus electric efficiency may be improved. For example, since the number of charging times per day is relatively high due to the driving characteristics of a commercial vehicle, the waste heat of the battery 42 generated during charging may be available for heating the cabin 1, and thus the heating of the cabin 1 may be quickly performed at the beginning of the vehicle driving.

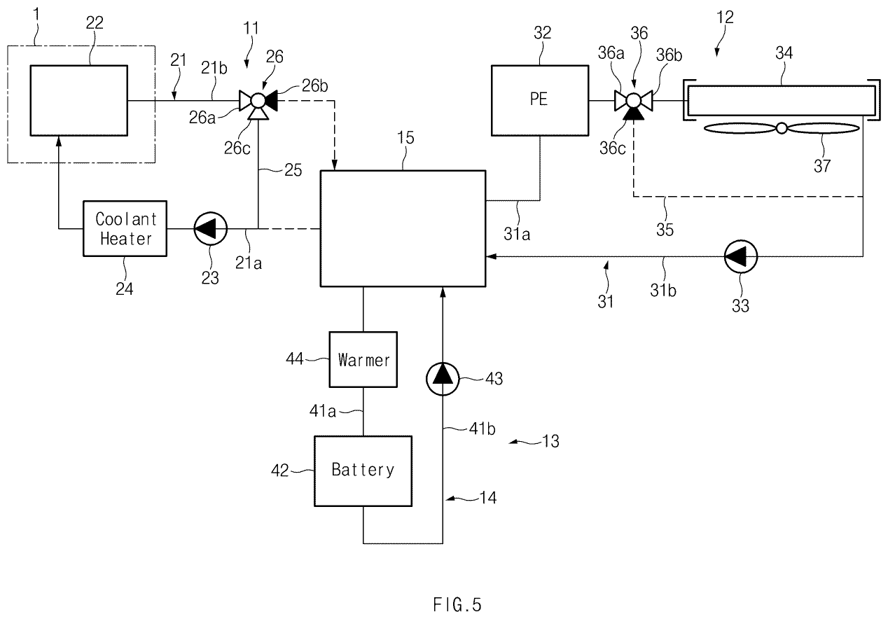

FIG. 5 illustrates a state in which the waste heat of the battery 42 is transferred to the PE cooling subsystem 12 through the heat pump module 15 and then is released outwards through the PE radiator 34 of the PE cooling subsystem 12 as the cabin heating subsystem 11 is thermally separated from the heat pump module 15, and the PE cooling subsystem 12 and the battery cooling subsystem 13 are thermally connected to the heat pump module 15 in summer.

Referring to FIG. 5, as the waste heat of the battery 42 and the waste heat of the PE component 32 are not available for heating the cabin 1 in summer, the controller may allow the control valve 26 of the cabin heating subsystem 11 to perform the second switching operation. Accordingly, the inlet port 26a may be allowed to communicate with the second outlet port 26c so that the cabin coolant discharged from the cabin radiator 22 may be directed to the bypass line 25 to thereby bypass the heat pump module 15.

Referring to FIG. 5, the controller may allow the control valve 36 of the PE cooling subsystem 12 to perform the first switching operation. Accordingly, the inlet port 36a may be allowed to communicate with the first outlet port 36b so that the PE coolant discharged from the coolant passage of the PE component 32 may pass through the PE radiator 34 and then be directed to the heat pump module 15. In addition, the battery coolant discharged from the battery 42 may be directed to the heat pump module 15.

Referring to FIG. 6, the controller may allow the first control valve 71 to perform the second switching operation so that the inlet port 71a may communicate with the second outlet port 71c. Accordingly, the refrigerant discharged from the compressor 52 may pass through the refrigerant passage 62a of the heat exchanger 62 through the first downstream line 51c and the second branch line 54, and the PE coolant discharged from the outlet line 31b of the PE coolant circulation path 31 may pass through the coolant passage 62b of the heat exchanger 62. As a result, heat may be transferred from the relatively high-temperature refrigerant to the relatively low-temperature PE coolant so that the refrigerant may be condensed, and the PE coolant may be heated. The heated PE coolant may be directed to the PE radiator 34 through the inlet line 31a of the PE coolant circulation path 31, and the PE coolant may release heat outwards through the PE radiator 34. The refrigerant discharged from the compressor 52 may not pass through the refrigerant passage 61a of the condenser 61, and the cabin coolant may not pass through the coolant passage 61b of the condenser 61. The controller may control the actuator of the first expansion valve 64 in a manner that allows the first expansion valve 64 to fully open (the opening degree of the first expansion valve 64 may be 100%). Accordingly, the refrigerant discharged from the refrigerant passage 62a of the heat exchanger 62 may not be expanded by the first expansion valve 64.

Referring to FIG. 6, the controller may control the actuator of the second expansion valve 65 in a manner that opens the second expansion valve 65 to a predetermined opening degree depending on the temperature of the battery 42. The refrigerant discharged from the refrigerant passage 62a of the heat exchanger 62 may be expanded by the second expansion valve 65. The refrigerant expanded by the second expansion valve 65 may pass through the refrigerant passage 63a of the evaporator 63 through the third branch line 55, and the battery coolant discharged from the outlet line 41b of the battery coolant circulation path 41 may pass through the coolant passage 63b of the evaporator 63. As a result, heat may be transferred from the relatively high-temperature battery coolant to the relatively low-temperature refrigerant so that the refrigerant may be evaporated, and the battery coolant may be cooled.

As described above, in a state in which the cabin heating subsystem 11 is not thermally connected to the heat pump module and the PE cooling subsystem 12 and the battery cooling subsystem 13 are thermally connected to the heat pump module 15 in summer, the refrigerant in the evaporator 63 may absorb heat from the battery coolant, the PE coolant in the heat exchanger 62 may absorb heat from the refrigerant, and the PE coolant may release heat outwards through the PE radiator 34. During the charging of the battery 42, the heat generating amount of the battery 42 may be relatively high, and the heat generating amount of the PE component 32 may be very low, and accordingly the waste heat of the battery 42 may be transferred to the PE radiator 34 of the PE cooling subsystem 12 through the heat pump module 15 so that the battery 42 may be efficiently cooled by the PE radiator 34, and power consumption of the cooling fan 37 may be relatively reduced. In particular, the refrigerant in the heat exchanger 62 may be sufficiently condensed by the PE coolant, and the refrigerant in the evaporator 63 may be sufficiently evaporated by the battery coolant. Accordingly, a difference between the inlet-side pressure and outlet-side pressure of the compressor 52 may be maintained at an appropriate level, and thus power consumption of the compressor 52 may be relatively reduced. Meanwhile, since the heat generating amount of the battery 42 when the vehicle is driving is much lower than the heat generating amount of the battery 42 when the vehicle is charging, the battery 42 may be sufficiently cooled by the PE radiator 34.

As set forth above, the vehicle thermal management system according to the embodiments of the present disclosure efficiently transfers heat between the cabin heating subsystem, the PE cooling subsystem, and the battery cooling subsystem through the heat pump module including the refrigerant cycle.

According to the embodiments of the present disclosure, the waste heat of the battery and the waste heat of the PE component may be available for heating the cabin in winter. Accordingly, a battery radiator may be removed, and thus the manufacturing cost is reduced. The operating time of the cooling fan of the PE cooling subsystem may be reduced, and thus electric efficiency is improved. For example, since the number of charging times: per day is relatively high due to the driving characteristics of a commercial vehicle, the waste heat of the battery generated during charging may be available for heating the cabin, and thus the heating of the cabin may be quickly performed at the beginning of the vehicle driving.

According to the embodiments of the present disclosure, in a state in which the cabin heating subsystem is not thermally connected to the heat pump module and the PE cooling subsystem and the battery cooling subsystem are thermally connected to the heat pump module in summer, the refrigerant in the evaporator may absorb heat from the battery coolant, the PE coolant in the heat exchanger may absorb heat from the refrigerant, and the PE coolant may release heat outwards through the PE radiator.

Hereinabove, although the present disclosure has been described with reference to some embodiments and the accompanying drawings, the present disclosure is not limited thereto, but may be variously modified and altered by those having ordinary skill in the art to which the present disclosure pertains without departing from the spirit and scope of the present disclosure.

What is claimed is:

1. A vehicle thermal management system, comprising:
a cabin heating subsystem thermally connected to a cabin and including a cabin coolant circulation path configured to allow a cabin coolant to circulate;
a power electronics (PE) cooling subsystem fluidly connected to a PE component and including a PE coolant circulation path configured to allow a PE coolant to circulate;
a battery cooling subsystem fluidly connected to a battery and including a battery coolant circulation path configured to allow a battery coolant to circulate; and
a heat pump module thermally and fluidly connected to the cabin heating subsystem, the PE cooling subsystem, and the battery cooling subsystem, wherein the heat pump module includes a refrigerant circulation path configured to allow a refrigerant to circulate.

2. The vehicle thermal management system according to claim 1, wherein the heat pump module comprises: a compressor, a condenser disposed on a downstream side of the compressor, an evaporator disposed on a downstream side of the condenser, and a heat exchanger configured to transfer heat between the refrigerant received from the compressor or the condenser and the PE coolant.

3. The vehicle thermal management system according to claim 2, wherein the cabin coolant circulation path is thermally connected to the condenser, and
the battery coolant circulation path is thermally connected to the evaporator.

4. The vehicle thermal management system according to claim 2, wherein the condenser includes a refrigerant passage fluidly connected to the refrigerant circulation path, and a coolant passage fluidly connected to the cabin coolant circulation path.

5. The vehicle thermal management system according to claim 2, wherein the heat exchanger includes a refrigerant passage fluidly connected to the refrigerant circulation path, and a coolant passage fluidly connected to the PE coolant circulation path.

6. The vehicle thermal management system according to claim 5, wherein the heat pump module includes a first expansion valve configured to expand the refrigerant flowing from the condenser to the heat exchanger.

7. The vehicle thermal management system according to claim 2, wherein the evaporator includes a refrigerant passage fluidly connected to the refrigerant circulation path, and a coolant passage fluidly connected to the battery coolant circulation path.

8. The vehicle thermal management system according to claim 7, wherein the heat pump module includes a second expansion valve configured to expand the refrigerant flowing into the refrigerant passage of the evaporator.

9. The vehicle thermal management system according to claim 2, wherein the heat pump module further includes a first control valve configured to allow the refrigerant discharged from the compressor to be directed to the condenser or to bypass the condenser.

10. The vehicle thermal management system according to claim 2, wherein the heat pump module further includes a second control valve configured to allow the refrigerant discharged from the condenser to be directed to the heat exchanger or allow the refrigerant bypassing the condenser to be directed to a refrigerant passage of the heat exchanger.

11. The vehicle thermal management system according to claim 1, wherein the cabin heating subsystem comprises:
a cabin radiator fluidly connected to the cabin coolant circulation path,
a circulation pump forcing the cabin coolant to circulate, and
a bypass line configured to allow the cabin coolant to bypass the heat pump module.

12. The vehicle thermal management system according to claim 11, wherein the cabin heating subsystem further includes a control valve configured to allow the cabin coolant discharged from the cabin radiator to be directed to any one of the heat pump module and the bypass line.

13. The vehicle thermal management system according to claim 1, wherein the PE cooling subsystem comprises:
a circulation pump configured to force the PE coolant to circulate,
a PE radiator configured to cool the PE coolant through heat exchange with ambient air, and
a bypass line configured to allow the PE coolant to bypass the PE radiator.

14. The vehicle thermal management system according to claim 13, wherein the PE cooling subsystem further includes a control valve configured to allow the PE coolant discharged from a coolant passage of the PE component to be directed to any one of the PE radiator and the bypass line.
